(19) United States
(12) Patent Application Publication
(10) Pub. No.: US 2004/0021219 A1
(43) Pub. Date: Feb. 5, 2004

(54) Method of mounting integrated circuit die in a package using a solder preform having isolatable portions

(76) Inventor: James Studebaker, Indian harbour Beach, FL (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(21) Appl. No.: 10/210,445

(22) Filed: Aug. 1, 2002

(51) Int. Cl. H01L 23/52

(52) U.S. Cl. 257/704; 257/779; 257/786; 438/125

(57) ABSTRACT

A method of mounting an integrated circuit die on an inside surface of a cover for an IC package uses a solder preform having isolatable structures that provide connections to a plurality of metalized pads while allowing selective electrical isolation therebetween.

### FIELD OF THE INVENTION

The present invention generally relates to packaging integrated circuit (IC) die in packages. Further, the invention relates to preformed sheets of solder for use with two-piece IC packages having a solderable lid such as, but not limited to, a metal (or ceramic), hermetically sealed package.

### BACKGROUND OF THE INVENTION

Integrated circuits are often enclosed in a package to protect the delicate IC die from damage (a die is a single piece of silicon, GaAs, etc, cut from an IC wafer and may contain a single electronic device or an electrical circuit).

Many types of IC packages used in modern IC packaging systems employ a package body for housing a die, and a cover (or lid) that is attached to the body (see FIG. 1). The body 2 of the IC package contains a cavity 5 allowing a die 4 to be placed inside the package and bondwires 14 are then attached to die 4, connecting die 4 to package leads 18 for interfacing to other circuits outside the package (not shown). The body 2 and/or the cover 8 may be made from ceramic, metal, glass, plastic, or a combination of ceramic, metal, glass, or plastic. For example, one type of IC package body is composed of ceramic forming the walls and floor, with metal leads extending from the sides and/or bottom. A metal layer 6 is deposited on the tops of walls 22 to allow a cover 8 to be attached to the body. The corresponding cover 8 may be metal, or may be ceramic having a portion thereof layered with metal 10 that is the mirror image of the metal layer 6 on the package body 2. A sheet of solder 12, preformed to match the shape of the metal layer 6 on the tops of walls 22, and the metal layer 10 on cover 8 (with the center of the solder sheet removed), is placed on top of, and aligned with, the metal layer 6 on the package body 2. The cover 8 is then placed on top of the preformed solder sheet 12 (called a solder preform). The entire stacked combination of package body 3 containing the die, solder preform 12 and cover 8 are then heated to melt the solder preform. When the solder preform melts, the molten solder wets both the metal layer 6 on the package body and the corresponding metal portion 10 of the cover 8. After wetting, the stacked combination of package body 2 containing the die 4, solder preform 12 and cover 8 are cooled which causes the solder to solidify and adhere to the metal surfaces thereby sealing the cover to the package body.

One problem associated with the type of packages described above is they require a large amount of space (area) on a printed circuit board (PCB), especially hermetically sealed packages. A small die, when packaged as described above, occupies a relatively large space on a PCB due to the package. It is therefore desirable to fill the space within a package of a given size, with as much (or as many) die as possible.

Some workers have installed die side by side in a package body. Though this approach conserves some package area, the package footprint increases nonetheless.

Workers have also stacked die on top of one another. This approach, though keeping package area from increasing, suffers from thermal management issues. The thermal load of the upper die must be sunk through the lower die (in addition to the thermal load of the bottom die). Electrical isolation may also be compromised with the stacked die approach and this must be taken into account during the design of the electrical circuitry on the die. Electrical isolation (e.g. Electro-Magnetic Interference—EMI) techniques can increase die area, which in turn drives package area.

### BRIEF DESCRIPTION OF THE DRAWINGS

FIG. 1 shows a prior art integrated circuit package body with IC die installed, a solder preform, and a cover for the package body.

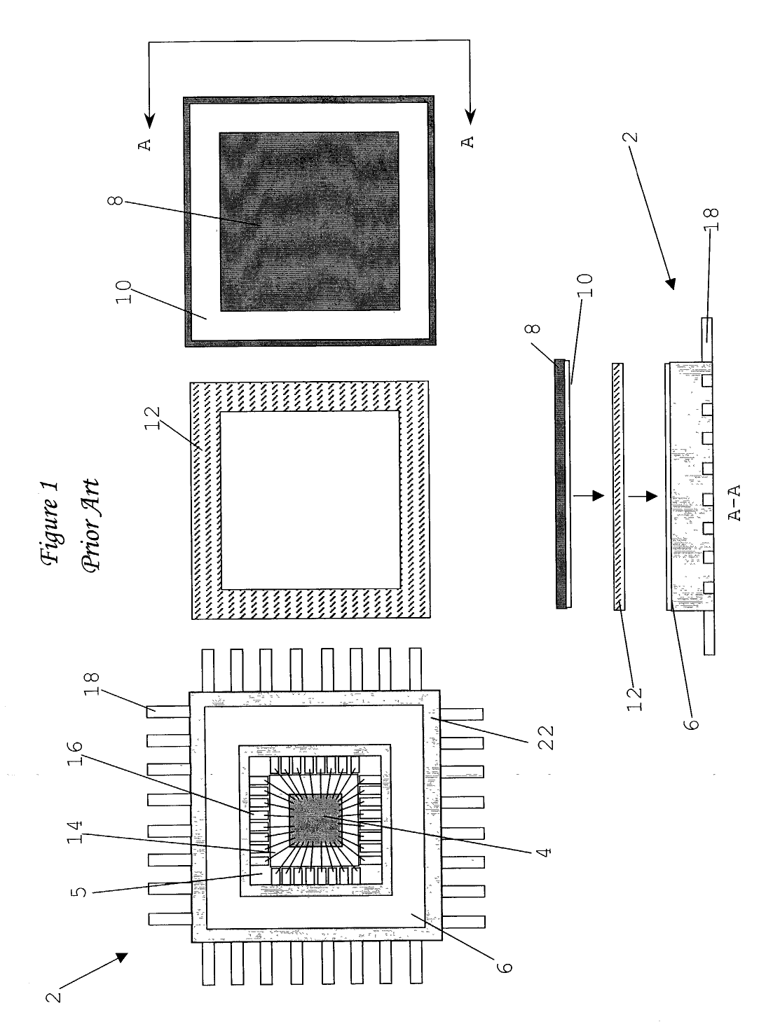

FIG. 2 shows an integrated circuit package body with IC die installed for use with the invention herein.

FIG. 3 shows an embodiment of the inventive integrated circuit package cover herein.

FIG. 4 shows an embodiment of the inventive solder preform herein.

FIG. 5 shows a solder preform in accordance with the invention herein, positioned on top of an embodiment of the inventive package body herein.

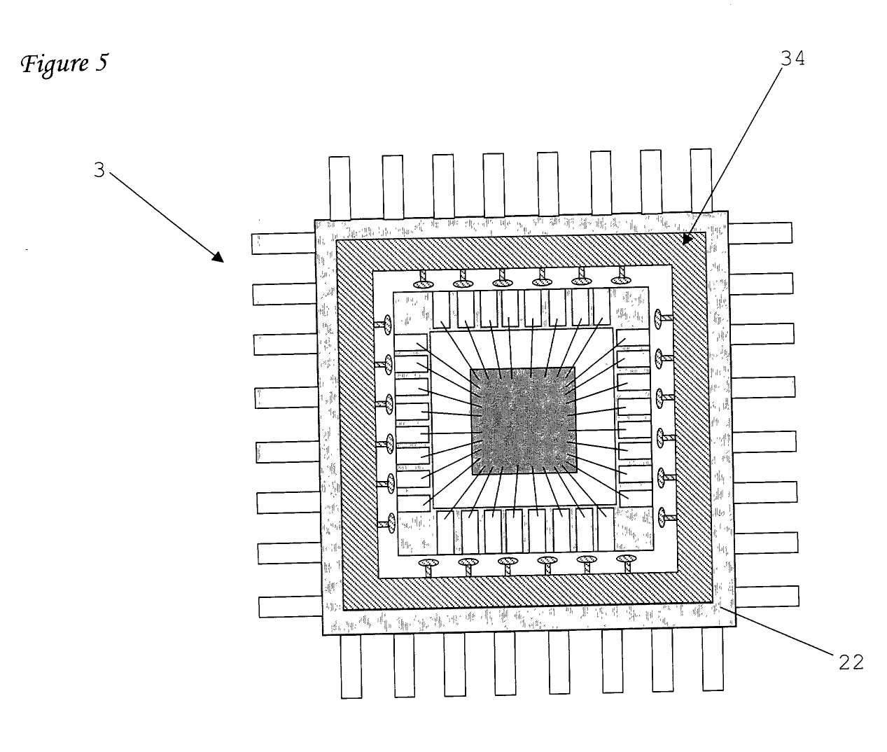

FIG. 6 is a side view of a package body, solder preform, and cover in accordance with the inventions herein just prior to placing the cover on top of the solder preform and package body.

FIG. 7 is a side view of a package body, solder preform, and cover in accordance with the inventions herein just after placing the cover on top of the solder preform and package body, and prior to melting the solder preform.

FIG. 8 is a side view of a package body, solder preform, and cover in accordance with the inventions herein just after melting the solder preform.

### SUMMARY OF THE INVENTION

It is an object of the invention herein to provide a solder preform having cantilevered portions that separate from the remaining part of the solder preform upon melting of the preform.

It is an object of the invention herein to provide a solder preform having portions that are isolatable from each other and from the remaining part of the solder preform upon melting of the preform, so as to connect a plurality of electrical contacts without shorting said plurality of electrical contacts together.

It is a further object of the invention herein to provide a structure and method of mounting a first IC die on the underside of a cover for an IC package having a second die installed in the package body.

It is another object of the invention herein to define a method for providing electrical connections between a first die mounted on a cover to be attached to a package body, and a second die mounted in said package body using a solder preform in accordance with the invention herein.

It is another object of the invention herein to define a method for providing electrical connections between a first die mounted on a cover to be attached to a package body, and leads extending outside the package body using a solder preform in accordance with the invention herein, without making electrical connections to a second die mounted in said package body.

The invention herein provides a solder preform having sections that are isolatable from at least the main body of the preform upon melting of the preform.

The inventive solder preform is positioned between a body of an IC package and a corresponding cover for said IC package body. Some first portions of the solder preform are placed in contact with metalized portions of the package cover and/or IC package body. Other second portions of the solder preform are not in contact with metalized portions of the cover and/or body. The second portions of the preform that are not in contact with metalization, exist between two other first portions that are in contact with metalization. Upon application of sufficient heat, the solder preform melts and subsequently wets the metalized areas it is in contact with. Molten solder has the characteristic of being drawn towards the heated metalized portions that the solder is in contact with, much like a loose strand of solder is drawn onto the tip of a hot soldering iron. The first portions of molten solder that are in contact with metalization and are flanking a second portion of solder, exert a tensile force on the second portion sufficient to separate or break the molten solder into two parts that each subsequently flow to the different metalized sections.

The inventive solder preform and inventive methods herein allow more IC die to be installed into a package of given size than was previously possible. The invention herein solves the problems of thermal management and growth of package area on a PCB. Further, the invention herein allows multiple die to be electrically connected together if desired. This means that die that ordinarily would be packaged separately, may now be packaged together saving precious PCB space.

### DESCRIPTION OF THE INVENTION

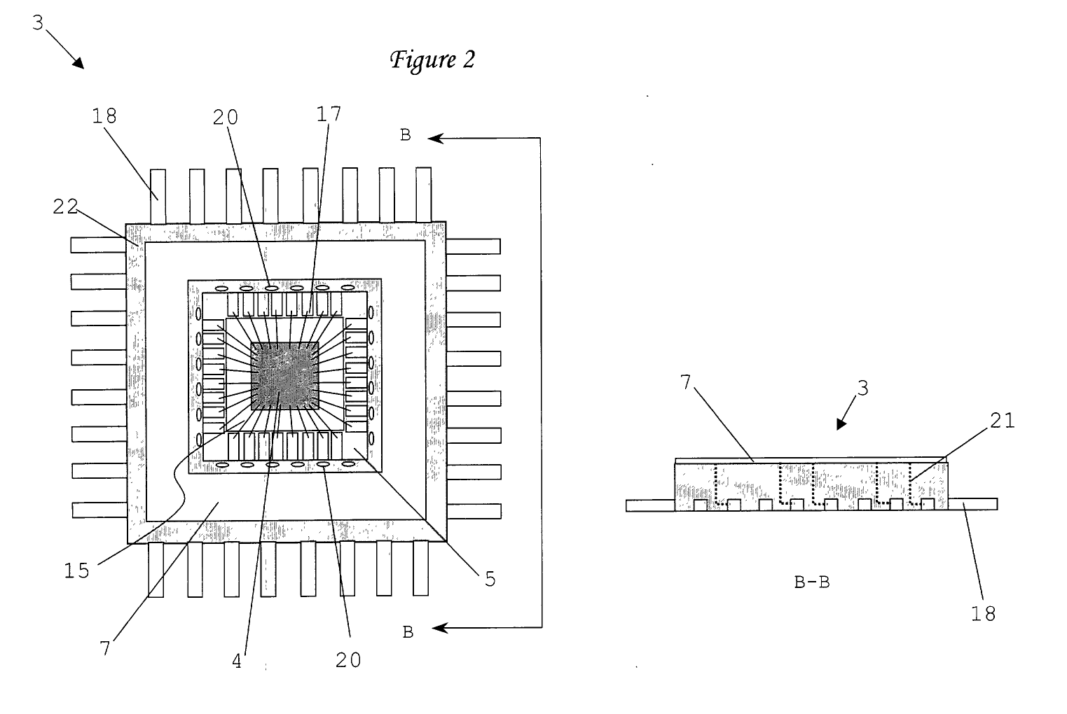

An integrated circuit (IC) package body 3 in accordance with the invention herein is shown in FIG. 2. Package body 3 may have an IC die 4 installed in the cavity 5 of the package as is generally known in the art. Die 4 may be connected to external leads 18 via bondwires 15 and pads 17 or may be mounted in flip-chip fashion (not shown). Body 3 has a plurality of metalized pads 20 affixed to the tops of walls 22. Pads 20 may be connected via connections 21 to external leads 18, or to internal pads 17 (which also may or may not be connected to external leads 18) for subsequent connection to die 4. Connections 21 may be buried circuit traces as is known or may be vertical circuit traces deposited on the inside walls of body 3 (not shown).

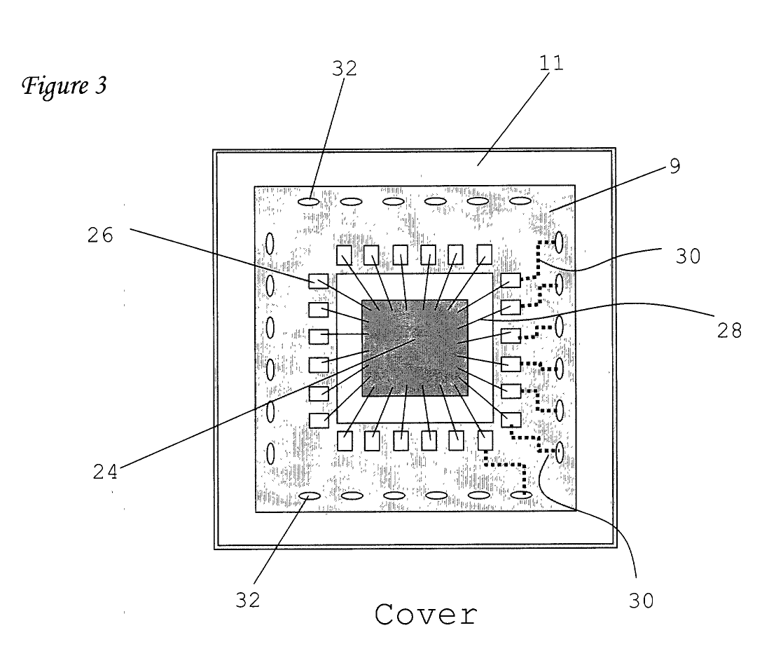

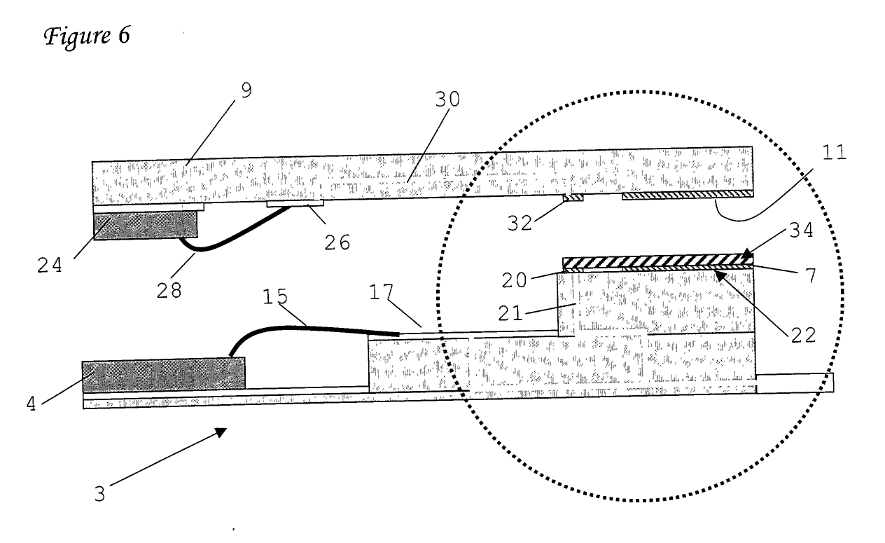

Cover 9, shown in FIG. 3, has an IC die 24 mounted on an underside surface thereof that faces cavity 5 of body 3 when cover 9 is soldered to body 3 (see FIG. 6). Cover 9 has metalized pads 32 deposited on the underside surface such that when cover 9 is inverted and positioned on body 3, pads 32 are aligned over pads 20. Cover 9 also has pads 26 that are connected to die 24 via wirebonds 28. Pads 26 are connected to pads 32 via metalized circuit traces 30 that may buried or exposed traces as is well known. Cover 9 has an area of metalization 11 that is soldered to metalization area 7 on body 3 in the inventive manner described below. Metalization area 11 maybe electrically isolated from some or all of pads 32. Metalization area 7 on body 3 may also be electrically isolated from some or all of pads 20.

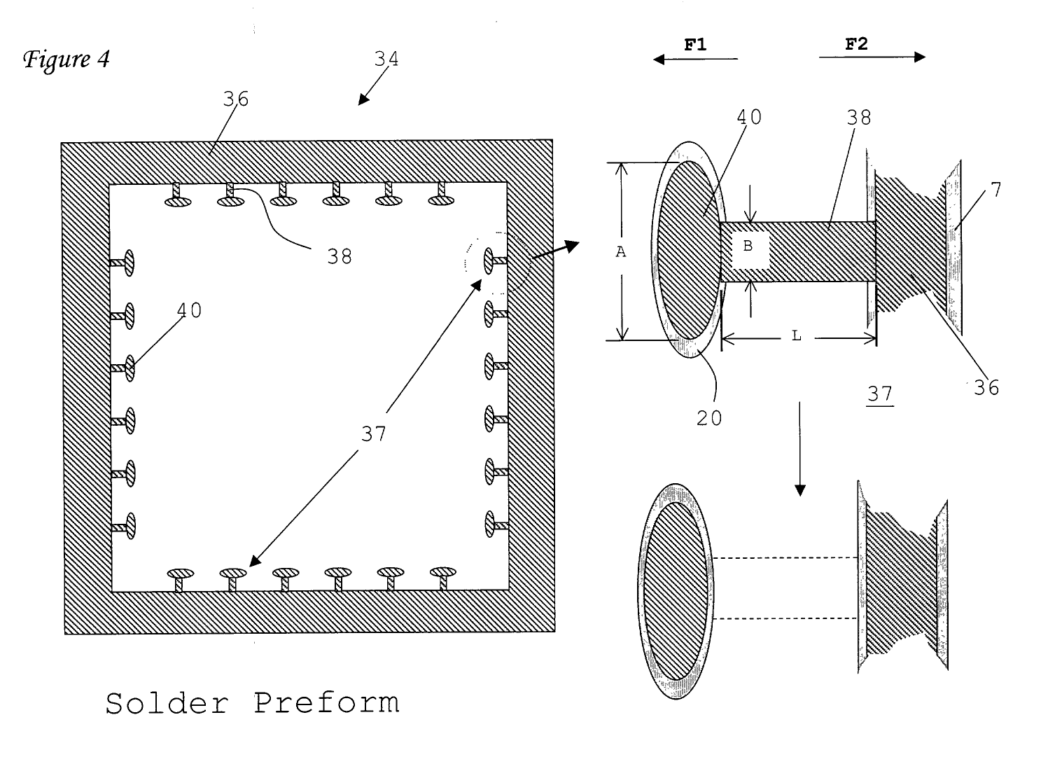

A solder preform 34 in accordance with the invention herein is shown in FIG. 4. Preform 34 comprises a main body 36 having a plurality of isolatable structures 37 protruding from main body 36 in a cantilevered fashion.

Main body 36 performs at least two functions, first, as a support structure for supporting said plurality of isolatable structures 37 during handling of solder preform 34 similar to the well-known lead frame. A lead frame (not shown) is a metallic frame containing leads and a package base to which an unpackaged integrated circuit die is attached. After encapsulation, the outer part of the lead frame (similar to main body 36) is cut away, discarded and the leads (which are attached to the package base) are bent into the required shapes.

Secondly, main body 36 is used for making a connection (sealing) between cover 9 and package body 3 when solder preform 34 is sufficiently heated to at least the melting point of the alloy used to manufacture solder preform 34.

Though isolatable structures 37 are shown on the inside edges of main body 36, this is not to be construed as a limitation of the invention herein as isolatable structures 37 may also be positioned on an outside edge of main body 36 (not shown). Each of isolatable structures 37 consist of a distal portion 40 and a proximal portion 38. Proximal portion 38 connects distal portion 40 to the main body 36. In use, solder preform 34 is positioned on a substrate that is only partially patterned with metalized areas. Referring to FIG. 4, distal portion 40 and main body 36 (only a portion of which is shown) is positioned on metalized areas 20 and 7 respectively. Proximal portion 38 is positioned on a non-metalized area such as ceramic (alternatively, a metal cover may be selectively coated with a material suitable to prevent molten solder from wetting and adhering to it). When solder preform 34 (including distal portion 40 and proximal portion 38) and metalized areas 20, & 7 are sufficiently heated, solder preform melts and transitions to a molten state. The molten solder wets and adheres to metalized areas 7 and 20 creating opposing forces F1 and F2 that are exerted on proximal portion 38 in tension as shown in FIG. 4. Opposing forces F1 and F2 are sufficiently large to cause distal portion 40 to separate from proximal portion 38. Surface tension draws proximal portion 38 onto one or both metalized areas 7 and/or 20 to become part of distal portion 40 and/or main body 36. Distal portion 40 is now isolated from main body 36.

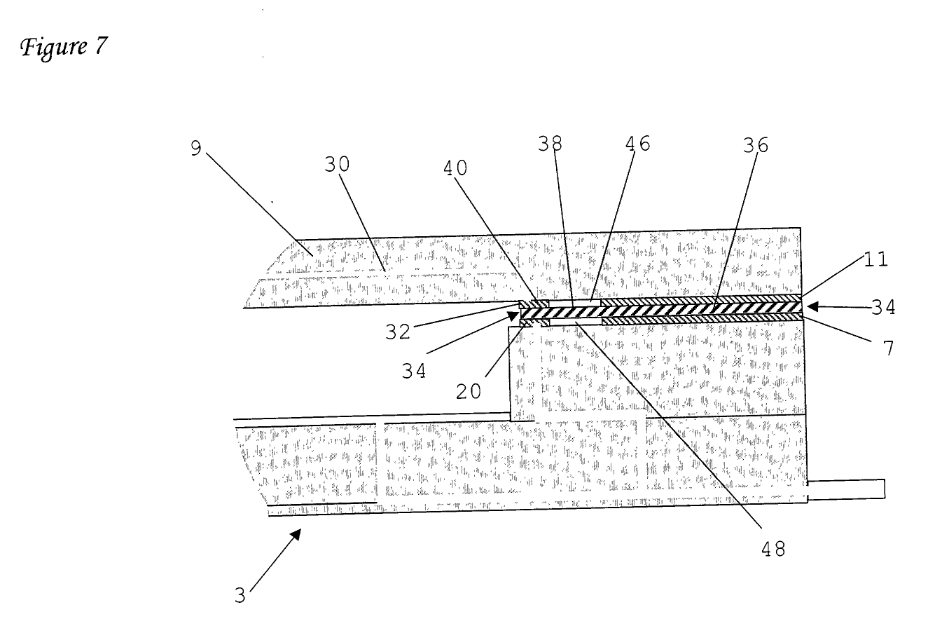

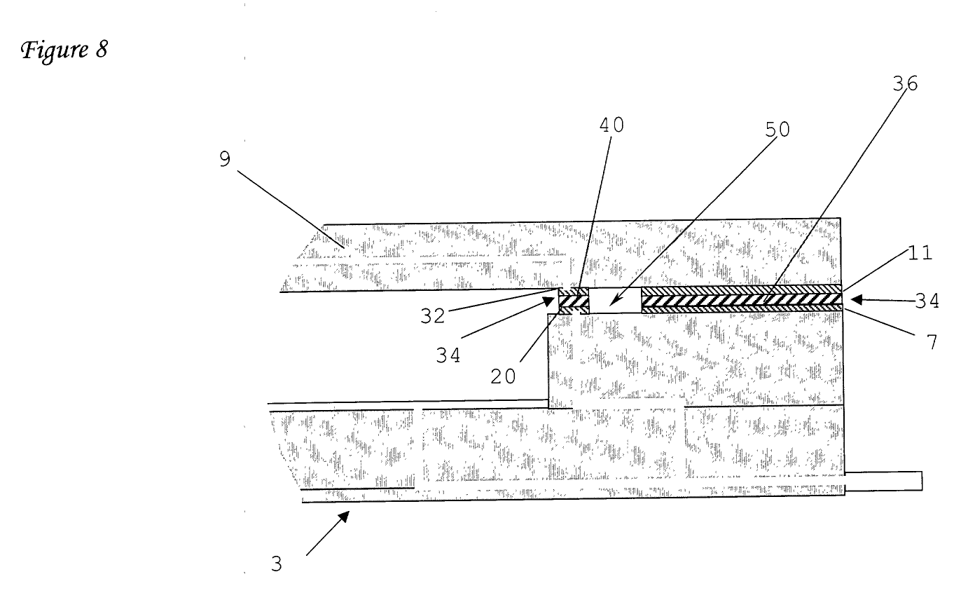

Solder preform 34 is placed onto package body 3 such that distal portions 40 are aligned with and on pads 20, and main body 36 is aligned with and on metalized area 7 of package body 3. Cover 9, with die 24 mounted thereon, is then inverted and placed on solder preform 34 (and subsequently package body 3) such that pads 32 are aligned with, and on, distal portion 40, and metalized area 11 (of cover 9) is aligned with, and on, main body 36 as shown in FIGS. 6-8. Proximal portion 38 is shown in FIG. 7 as being bounded by two small gaps 46 and 48. These gaps are due to the thickness of metalized areas 7, 11, 20, and 32. Gaps 46 and 48 may assist in causing distal portion 40 from separating from proximal portion 38 once solder preform 34 enters the molten state and wets metalized areas 7, 11, 20, and 32. After distal portion 40 separates from proximal portion 38, gaps 46 and 48 combine to form a larger gap 50 that isolates distal portion 40 from main body 36 as shown in FIG. 8. Referring to FIGS. 6 and 8, it is clearly seen that an electrical connection between die 4 mounted in package body 3 and die 24 mounted on cover 9 is completed. Said electrical connection is made via bondwire 28, pad 26, trace 30, pad 32, distal portion 40, pad 20, traces 21, pad 17, and bondwire 15.

Solder preform 34 is described herein as being used to mount a single IC package. The invention herein is not limited to such.

As is well known in the art, electrically conductive epoxy (or solder paste) is deposited on a substrate or printed circuit board in a predetermined pattern using automatic epoxy dispensers. The epoxy dispensers deposit small “dots” of conductive epoxy (or solder paste) on metalized pads. Electrical components are then placed on the epoxy/pad combination and cured (or solder paste melted) thereby creating an electrical connection between the pad and a terminal of the electrical component. The inventive solder preform 34 may be used as described supra in lieu of depositing epoxy or solder paste dots. The inventive solder preform 34 may also be used to replace silkscreening operations where solder paste is deposited on a substrate using a mask made of metal as is well known in the art. Unwanted electrical “shorts” between electrical components will not occur using the inventive solder preform 34 because isolatable structures 37 separate from main body 36 as well as other isolatable structures that may or may not be present as part of solder preform 34. Multiple solder preforms 34 in accordance with the invention herein may be used on the same substrate, each having a different geometry.

I claim:

1. A solder preform comprising;
a main body operative to support a plurality of isolatable structures;
a plurality of isolatable structures for connecting metalized areas together, each of said isolatable structures comprising:
a proximal portion having a first end cantileveredly attached to said main body; and
a distal portion attached to a second end of said proximal portion, said distal portion for connecting some of said metalized areas together;
wherein said distal portion separates from said proximal portion when said solder preform is sufficiently heated; and
wherein said proximal portion becomes part of said main body and/or said distal portion after said distal portion separates from said proximal portion.

2. The solder preform of claim 1 wherein said distal portion has a dimension A that is larger than a dimension B of said proximal portion.

3. The solder preform of claim 2 wherein said proximal portion has a length that is greater than said dimension A of said distal portion.

4. The solder preform of claim 1 wherein said proximal portion has a length that is greater than a dimension A of said distal portion.

5. The solder preform of claim 1 wherein said plurality of metalized surfaces comprise a cover and a portion of an integrated circuit package body.

6. A method of packaging integrated circuit die comprising:
providing a body having a plurality of first metalized pads deposed on a surface thereof, said body having a cavity operable to house at least one integrated circuit die;
providing a cover operable to seal said body, said cover having a plurality of second metalized pads deposed on a surface of said cover, wherein said surface having said plurality of second metalized pads faces inwards toward said cavity such that said plurality of first metalized pads and said plurality of second metalized pads are aligned thereto;
providing a solder preform having a main body operative to support a plurality of isolatable structures, each of said isolatable structures comprising a proximal portion having a first end cantileveredly attached to said main body and a distal portion attached to a second end of said proximal portion, said distal portion operable to connect at least some of said first and said second plurality of metalized pads together;
mounting a second integrated circuit die onto said surface of said cover and electrically connecting said second integrated die to at least some of said second plurality of metalized pads;
sandwiching said solder preform between said body and said cover so as to align said distal portion of each of said plurality of isolatable structures with at least some of said first and said second plurality of metalized pads; and
reflowing said solder preform.

7. The solder preform of claim 6 wherein said distal portion has a dimension A that is larger than a dimension B of said proximal portion.

8. The solder preform of claim 7 wherein said proximal portion has a length that is greater than said dimension A of said distal portion.

9. The solder preform of claim 6 wherein said proximal portion has a length that is greater than a dimension A of said distal portion.

10. An integrated circuit comprising:
a package body having a plurality of first metalized pads deposed on a surface thereof, said package body having a cavity operable to house at least one integrated circuit die;
a cover mateable with said package body, said cover operable to seal said package body, said cover having a plurality of second metalized pads deposed on a surface of said cover, wherein said surface having said plurality of second metalized pads faces inwards toward said cavity such that said plurality of first metalized pads and said plurality of second metalized pads are aligned thereto; and
a plurality of solder connections formed by reflowing a solder preform, said solder preform having a main body operative to support a plurality of isolatable structures, each of said isolatable structures comprising a proximal portion having a first end cantileveredly attached to said main body and a distal portion attached to a second end of said proximal portion, said distal portion operable to connect at least some of said first and said second plurality of metalized pads together.

11. The integrated circuit of claim 10 wherein said distal portion has a dimension A that is larger than a dimension B of said proximal portion.

12. The integrated circuit of claim 11 wherein said proximal portion has a length that is greater than said dimension A of said distal portion.

13. The integrated circuit of claim 10 wherein said proximal portion has a length that is greater than a dimension A of said distal portion.
